(19) United States
(12) Patent Application Publication
(10) Pub. No.: US 2007/0281089 A1
(43) Pub. Date: Dec. 6, 2007

(54) Systems and methods for roll-to-roll atomic layer deposition on continuously fed objects

(75) Inventors: Christian Maria Anton Heller, Albany, NY (US); Ahmet Gun Erlat, Clifton Park, NY (US); Eric Michael Breitung, New York, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/446,077

(22) Filed: Jun. 5, 2006

(51) Int. Cl. C23C 16/00

(52) U.S. Cl. 427/255.5; 118/718; 427/255.7

(57) ABSTRACT

Embodiments of the invention include a roll-to-roll atomic layer deposition (ALD) device. The device includes mechanisms to enable relative movement between a substrate to be deposited upon and various chambers containing ALD precursor gases.

### BACKGROUND

The invention generally relates to the atomic layer deposition of materials, and more particularly, to atomic layer deposition onto continuously fed objects.

Atomic layer deposition (“ALD”) is a deposition technique that is suitable for fabricating conformal coatings, such as, for example, ultra-high permeation barriers. The term “ultra-high permeation barriers” shall mean barriers with a water vapor permeation rate of less than 0.1 grams/meter²/day (g/m²/day) and possibly as low as or less than 10⁻⁶ g/m²/day. One disadvantage with currently known ALD techniques is that they are relatively slow, for example, 0.1-1 nm/min. Specifically, known ALD techniques have a limited deposition rate due to the time required to alternate between the two precursor gases necessary to perform atomic layer deposition.

Another disadvantage with currently known ALD techniques is that they are performed on objects through a batch deposition process. Batch processing exacerbates the limited deposition rate found in known ALD techniques.

Therefore, there is a need for an ALD technique that alleviates some of the deficiencies noted in known ALD techniques.

### SUMMARY

One embodiment of the invention described herein is directed to a continuous roll-to-roll atomic layer deposition device.

One aspect of the continuous roll-to-roll atomic layer deposition device includes at least one first chamber adapted for receiving a first precursor gas, at least one second chamber adapted for receiving a second precursor gas, and at least one roller configured to allow a substrate to be transported through the first and second chambers. The first precursor gas forms a first monolayer on the substrate and the second precursor gas forms a second monolayer on the first monolayer to form a layer of a desired film. This cycle may be repeated to attain a desired thickness.

Another embodiment of the invention is a method for roll-to-roll atomic layer deposition of a coating on a substrate. The method includes introducing a first gas source to a first location, inducing relative motion between a substrate and the first location, introducing a second gas source to a second location, and inducing relative motion between the substrate and the second location. A first precursor gas from the first gas source forms a first monolayer on the substrate and a second precursor gas from the second gas source forms a second monolayer on the first monolayer.

These and other advantages and features will be more readily understood from the following detailed description of preferred embodiments of the invention that is provided in connection with the accompanying drawings.

### BRIEF DESCRIPTION OF THE DRAWINGS

FIG. 1 is a schematic view of a roll-to-roll atomic layer deposition device constructed in accordance with an exemplary embodiment of the invention.

FIG. 2 is a schematic view of a roll-to-roll atomic layer deposition device constructed in accordance with an exemplary embodiment of the invention.

FIG. 3 is a schematic view of a roll-to-roll atomic layer deposition device constructed in accordance with an exemplary embodiment of the invention.

FIG. 4 is a side view of a roll-to-roll atomic layer deposition device constructed in accordance with an exemplary embodiment of the invention.

FIG. 5 is a partial side view of an aspect of the baffles and deposition chambers of the device of FIG. 4.

FIG. 6 is a partial side view of an aspect of the baffles and deposition chambers of the device of FIG. 4.

FIG. 7 is an exploded view of the baffle shown in circle VII of FIG. 6.

FIG. 8 is a top view of a roll-to-roll atomic layer deposition device constructed in accordance with an exemplary embodiment of the invention.

FIGS. 9 and 10 are side and top views, respectively, of a roll-to-roll atomic layer deposition device constructed in accordance with an exemplary embodiment of the invention.

FIGS. 11 and 12 are side and top views, respectively, of a roll-to-roll atomic layer deposition device constructed in accordance with an exemplary embodiment of the invention.

FIG. 13 is a top view of a roll-to-roll atomic layer deposition device constructed in accordance with an exemplary embodiment of the invention.

FIG. 14 is a cross-sectional side view of a roll-to-roll atomic layer deposition device constructed in accordance with an exemplary embodiment of the invention.

FIG. 15 is a view of illustrating the baffle system of the device of FIG. 14.

FIG. 16 is a view of a first spacer of the device of FIG. 14.

FIG. 17 is a view of a second spacer of the device of FIG. 14.

FIG. 18 is a view of a third spacer of the device of FIG. 14.

FIG. 19 is a view of a fourth spacer of the device of FIG. 14.

FIG. 20 is a view of a fifth spacer of the device of FIG. 14.

FIG. 21 is a view of a sheet that of the device of FIG. 14.

FIG. 22 is a process for performing an atomic layer deposition upon a continuously fed object.

### DETAILED DESCRIPTION OF PREFERRED EMBODIMENTS

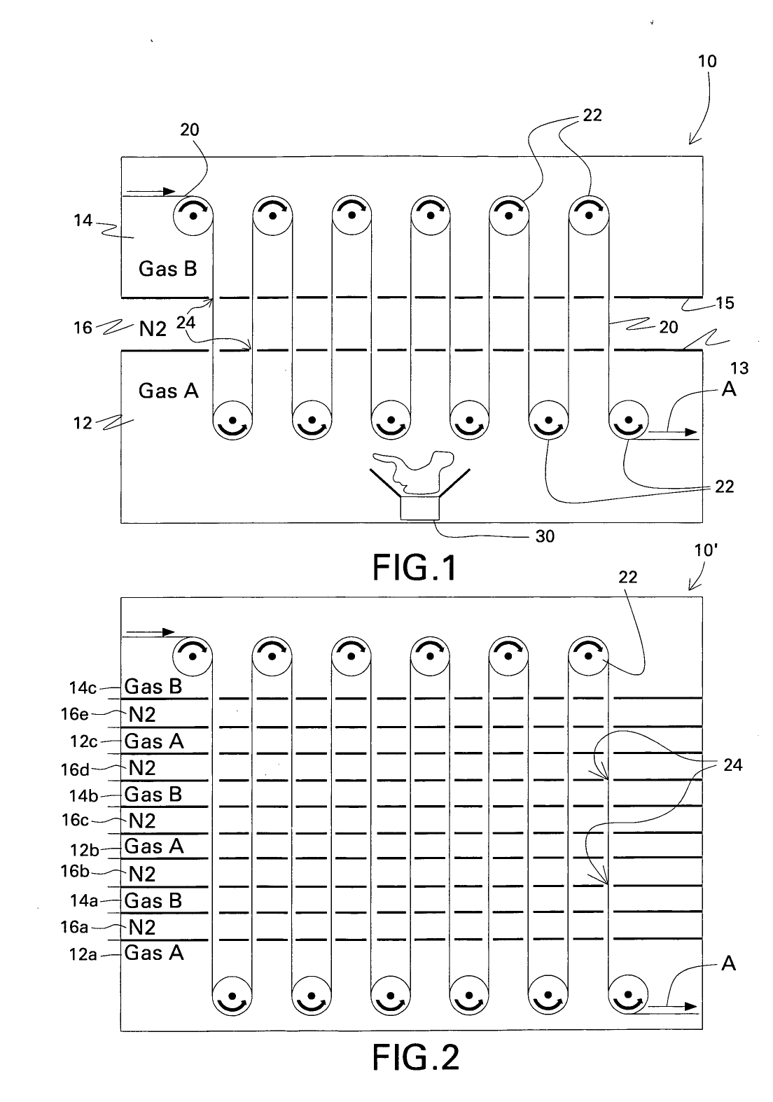

With specific reference to FIG. 1, there is shown a roll-to-roll atomic layer deposition (“ALD”) device 10. The ALD device 10 is configured to enable the continuous movement of a substrate 20 through the device for the purpose of performing an atomic layer deposition procedure on the substrate. Examples of substrates 20 upon which atomic layer deposition may occur include plastic film, plastic sheet, metal sheet, metal film, glass sheet, optoelectronic devices that have been built on glass, metal or plastic substrates, and any other materials requiring an ultra-high barrier coating. While the description of the roll-to-roll ALD device indicates a single substrate 20 being deposited upon, it should be appreciated that instead a web may be utilized to transport continuously fed discrete objects. Possible applications for the ALD process include organic light-emitting devices (OLEDs), flexible display coatings, such as those for LCDs or electrophoretics, RFID, MEMS, optical coatings, electronics on flexible substrates, thin films on flexible substrates, electrochromics, and photovoltaics.

As shown in FIG. 1, the ALD device 10 includes a first ALD chamber 12, a second ALD chamber 14, and a third chamber 16 positioned there between. A first ALD precursor gas is introduced into the first ALD chamber 12, while a second ALD precursor gas is introduced into the second ALD chamber 14. The third chamber 16 is configured to receive a carrier gas, such as, for example, nitrogen or an inert gas, such as, for example, argon. The inert gas may be introduced into the chamber 16 at a pressure higher than the first and second ALD precursor gases are introduced into their respective chambers 12, 14.

The first ALD chamber 12 is separated from the third chamber 16 by a wall 13, and the second ALD chamber 14 is separated from the third chamber 16 by a wall 15. Each of the walls 13, 15 includes a plurality of baffles 24 through which the substrate 20 extends. The walls 13, 15 are preferably formed of a material that is compatible with the targeted ALD gases and ALD process conditions. Contact between the substrate 20 and the walls 13, 15 should be minimized to inhibit imperfections in the substrate 20. The baffles 24 are sized and shaped to address two criteria: (a) to inhibit the likelihood that a surface of the substrate 20 will come in contact with either of the walls 13, 15; and (b) to inhibit the premature intermixing of the first and second ALD precursor gases.

A plurality of rollers 22 are positioned in each of the first and second ALD chambers 12, 14, and the substrate is wound around the rollers 22 and through the baffles 24 so that the substrate 20 may be transported through each of the chambers 12, 14, 16. The rollers 22 may be drums, spindles, spools, or other like devices configured for being rotated. It should be appreciated that a motion may be imparted on the substrate 20 by a force in the direction A (as shown), or instead a motion may be imparted on the substrate 20 by a force in the direction opposite of direction A. Each of the rollers 22 may be positioned so that the substrate 20 unwinds off a particular roller 22 and extends vertically toward the next roller 22. Through such an arrangement, design of the baffles 24 in the walls 13, 15 is simplified. By moving the substrate 20 through the ALD chambers 12, 14, multiple layers can be formed in a relatively short amount of time.

It should be understood that minimal contact is to be maintained between the rollers 22 and the substrate 20. This may be accomplished through the use of rollers 22 being spool-shaped (having a larger diameter toward its ends) and the substrate 20 resting upon the larger diameter portions of the rollers 22. Alternatively, the rollers 22 may include grabbing implements at its edges that obtain a grasp of the substrate 20 as it winds around each roller 22. Through either arrangement, it should be appreciated that upon finalizing the atomic layer deposition, the portions of the substrate 20 having come in contact with any portion(s) of the rollers 22 may be sliced off.

An optional plasma source 30 may be positioned within one of the ALD chambers 12, 14 or both. Use of the plasma source 30, or other surface activation techniques, such as, for example, electron-beam, ultraviolet, ozone, and corona, may increase the reaction rate and improve layer quality. Optionally, AC or DC sputtering may be performed in conjunction with the roll-to-roll procedure. Such sputtering increases chemical reaction rates, reduces the optimal substrate temperature, and may lead to a denser deposition. For such an arrangement, the walls 13, 15 should be formed of a non-metallic and non-magnetic material.

It should also be appreciated that heat may be imparted onto the substrate to assist in the ALD procedure. Any suitable technique for imparting heat into the system should be sufficient. For example, the rollers 22 may be heated, or the precursor gases may be pre-heated or put through a heating mechanism prior to being introduced into the ALD chambers. Further, heat may be radiated through the chambers with heaters on the walls 13, 15. The heat sufficient for the ALD procedure should be anywhere from room temperature to 400° C.

Referring now to FIG. 2, there is shown a roll-to-roll ALD device 10′, which includes a plurality of first ALD chambers 12_{a-c}, a plurality of second ALD chambers 14_{a-c}, and a plurality of third chambers 16ₐ₋ₑ. As shown, each third chamber 16 is sandwiched between one first ALD chamber 12 and one second ALD chamber 14. Baffles 24 are formed in the walls of each of the chambers 12ₐ-16ₑ. The rollers 22 are located in first ALD chamber 12ₐ and second ALD chamber 14_{c}. The third chambers 16ₐ₋ₑ are adapted for receiving a carrier gas, such as nitrogen, so as to inhibit premature intermixing of the gases received in the first ALD chambers 12_{a-c} with the gases received in the second ALD chambers 14_{a-c.}

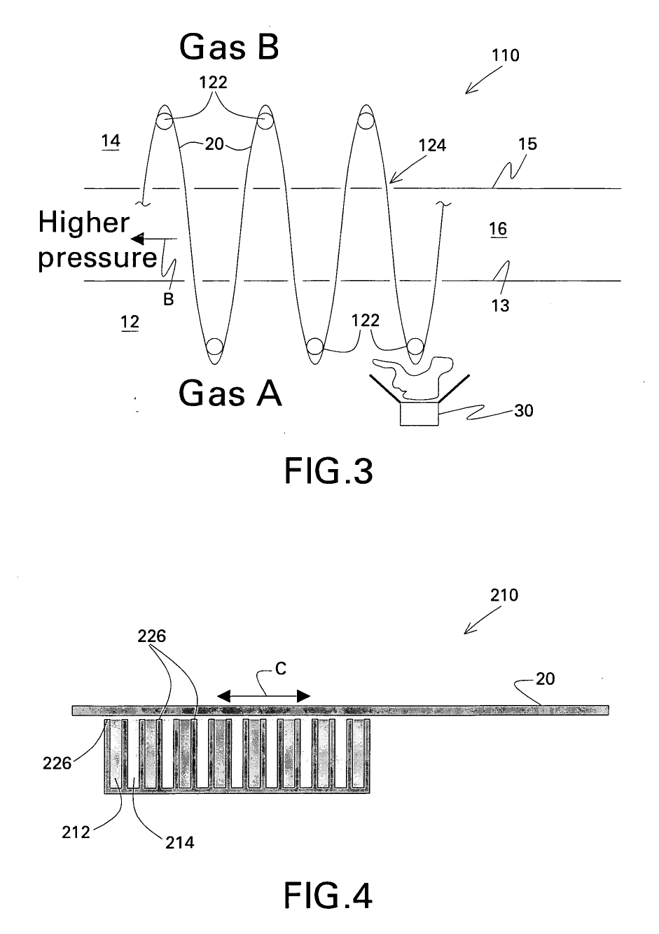

FIG. 3 illustrates a roll-to-roll ALD device 110 that includes a first ALD chamber 12 and a second ALD chamber 14 separated by a third chamber 16. Rollers 122 are positioned in the first and second ALD chambers 12, 14. The rollers 122 differ from the rollers 22 (FIGS. 1, 2) only in their size and positioning relative to the baffles. Specifically, the rollers 122 are smaller than the rollers 22. Also, the rollers 122 are positioned relative to the baffles 124 so that the substrate 20 extends through each baffle 124 at angle that is not ninety degrees to the walls 13, 15. Thus, the baffles 124 are configured somewhat larger than the baffles 24 to accommodate the substrate 20. The third chamber 16 is maintained at a higher pressure than the pressure maintained in the ALD chambers 12, 14. The higher pressure may be maintained by flowing an inert gas through the third chamber 16 at a velocity sufficient to induce the higher pressure. The inert gas may be flowed in the direction B, a direction opposite to direction B, or a direction orthogonal to direction B, such as a direction directly into or out of the drawing. An optional plasma source 30 may be positioned in either of the ALD chambers 12, 14 or both.

FIG. 4 illustrates a roll-to-roll ALD device 210. The device 210 includes a plurality of first ALD chambers 212 sequentially interspersed with a plurality of second ALD chambers 214. Each of the chambers 212, 214 opens up to a surface of the substrate 20. Walls 226 separate the chambers 212, 214. As the substrate 20 moves in a direction C past the chambers 212, 214, each chamber sequentially receives a specific gas for atomic layer deposition on the substrate 20. Specifically, a first ALD precursor gas enters a first one of the first ALD chamber 212. As the substrate 20 moves over the first ALD chamber 212, the first ALD precursor gas creates a monolayer on the substrate 20. Then, a second ALD precursor gas enters a first one of the second ALD chamber 214. As the substrate 20 moves over the second ALD chamber 214, the second ALD precursor gas creates a second monolayer on the substrate 20. The process is continued as the substrate 20 moves over the additional chambers 212, 214. It should be appreciated that although the first and second ALD chambers 212, 214 are shown on one side of the substrate 20, additional ALD chambers 212, 214 may be positioned on an opposite side of the substrate 20 as well.

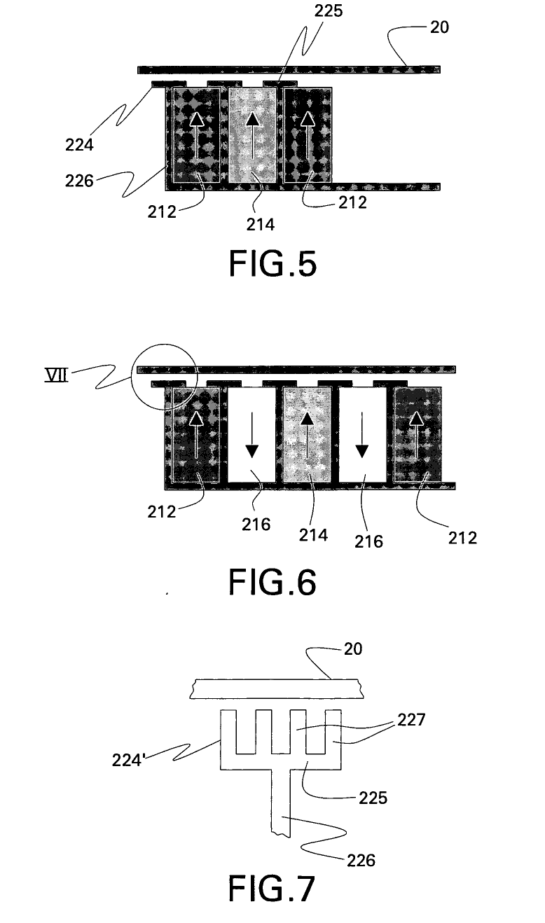

FIG. 5 illustrates a portion of the roll-to-roll ALD device 210. Particularly, FIG. 5 illustrates some of the chambers 212, 214. The walls 226 may include ledges 224 to inhibit premature intermixing of the first ALD precursor gas with the second ALD precursor gas. An alternative aspect of the roll-to-roll ALD device 210 is shown in FIG. 6. Specifically, a third chamber 216 is sandwiched between the first ALD chambers 212 and the second ALD chambers 214. The third chamber may receive an inert or carrier gas or, as shown, may impart at least a partial vacuum. Through this arrangement, premature intermixing of the ALD precursor gases is lessened.

FIG. 7 illustrates an alternative aspect to the ledge 224 shown in FIG. 5. Specifically, a ledge 224′ may be positioned at an end of each wall 226. The ledge 224′ includes a body portion 225 and a plurality of teeth 227. A purpose of the teeth 227 is to further reduce the flow of gases.

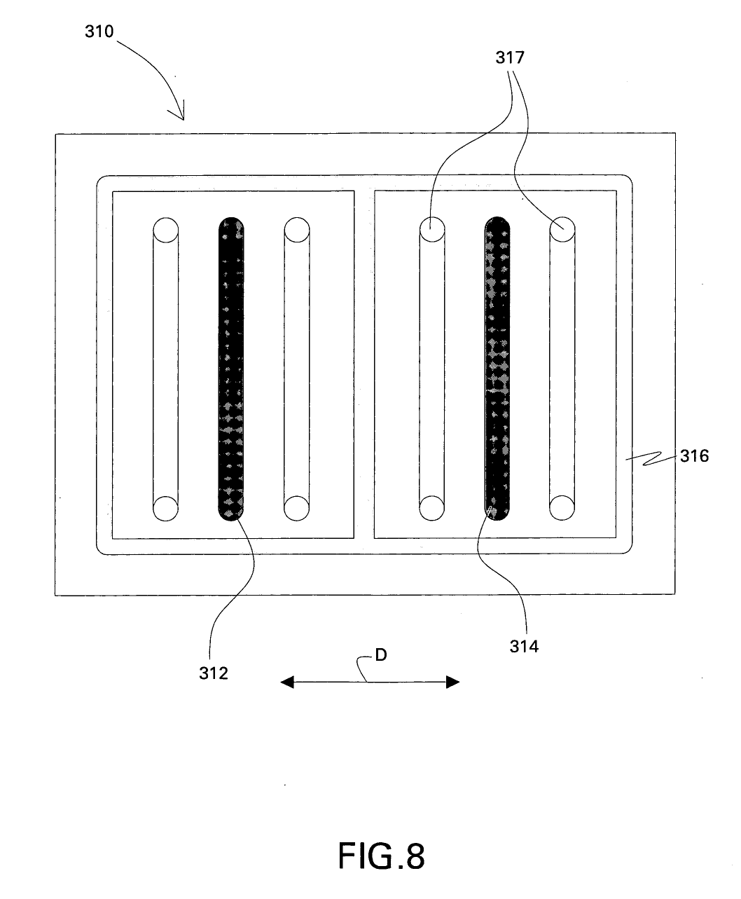

FIG. 8 illustrates a roll-to-roll ALD device 310 that includes a first ALD chamber 312, which receives a first ALD precursor gas, and a second ALD chamber 314, which receives a second ALD precursor gas. On either side of each of the chambers 312, 314 is a vacuum chamber 317, which imparts a vacuum to inhibit premature intermixing of the first ALD precursor gas with the second ALD precursor gas. Also included is a third chamber 316 surrounding the other chambers 312, 314, 317. The third chamber 316 imparts an inert gas to assist in lessening the likelihood that there is premature intermixing of the first ALD precursor gas with the second ALD precursor gas. A substrate 20 (not shown) is moved in a direction D across the face of the device 310. As the substrate 20 crosses over the chamber 312, the first ALD precursor gas creates a monolayer on the substrate 20. Remaining removable first ALD precursor gas may be dispersed by the third chamber 316, the vacuum chamber 317, or a combination of the two. Then, as the substrate 20 crosses over the chamber 314, the second ALD precursor gas creates a second monolayer on the substrate 20. It should be appreciated that the third chamber 316 may be configured to impart a vacuum and the chamber 317 may be configured to impart an inert or carrier gas.

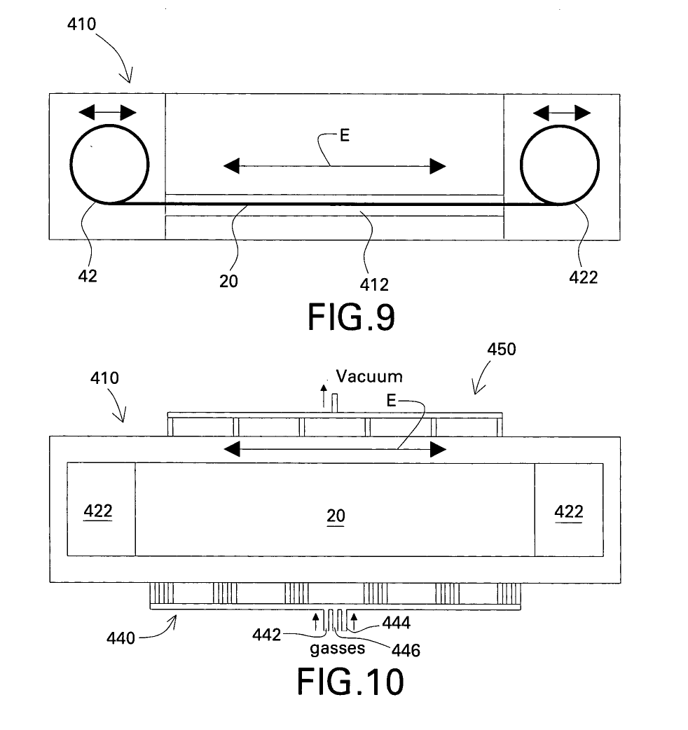

FIGS. 9 and 10 illustrate a roll-to-roll ALD device 410, which includes a single chamber 412 through which a substrate 20 extends. The substrate 20 is rolled in a direction E between rollers 422. Gas piping 440 is configured to enable ALD precursor gases to be sequentially added to the chamber 412. The gas piping 440 includes first piping 442 to receive and transmit a first ALD precursor gas to the chamber 412, a second piping 444 to receive and transmit a second ALD precursor gas to the chamber 412, and third piping configured to inhibit premature intermixing of the first ALD precursor gas with the second ALD precursor gas. The third piping may be carrier or inert gas piping 446 configured to receive and transmit a carrier gas or an inert gas to the chamber 412. Valving to allow for sequential introduction of the gases to the chamber 412 is not shown, but it should be appreciated that such valving is known in the art. Optionally, or alternatively, the third piping may be vacuum piping 450, which is configured to enable evacuation of the chamber 412.

In practice, the substrate 20 is extended into the chamber 412 and then a first ALD precursor gas is introduced. Once the reaction of the first ALD precursor gas with the substrate 20 has run its course (i.e., a monolayer has been created on the substrate 20), the first piping 442 is closed and a vacuum is imparted through the vacuum piping 450 to evacuate excess first ALD precursor gas from the chamber 412. Optionally, or alternatively, the carrier or inert gas piping 446 is opened to allow the introduction of the carrier or inert gas to the chamber 412. Optionally, the second piping 444 may be opened to allow the introduction of the second ALD precursor gas to the chamber 412.

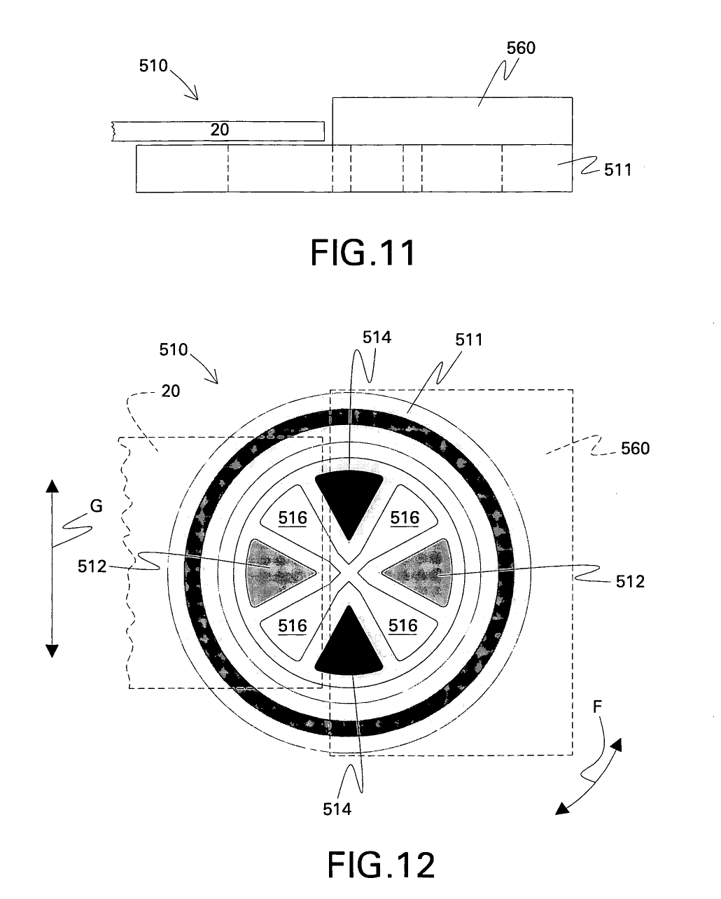

FIGS. 11 and 12 illustrate a roll-to-roll ALD device 510 that includes a rotating plate 511 and a cover 560. Although not shown, the rotating plate 511 is positioned on a rotating mechanism, such as, for example, a spin coater. The rotating plate 511 includes a plurality of chambers. Specifically, the rotating plate 511 includes at least one first chamber 512 adapted to accommodate and release a first ALD precursor gas, at least one second chamber 514 adapted to accommodate and release a second ALD precursor gas, and a plurality of third chambers 516 for accommodating and releasing an inert gas. The third chambers 516 are positioned between the first and second chambers 512, 514. Alternatively, and as shown, there may be a single third chamber 516 with portions thereof positioned between each of the first and second chambers 512, 514.

The rotating plate 511 is rotatable in a direction F, while the substrate 20 (FIG. 12) is moved in a direction G. The cover 560 covers a portion of the rotating plate 511, leaving unobstructed one chamber. In practice, the rotating plate 511 is rotated so as to leave unobstructed one of the first chambers 512 to allow the first ALD precursor gas to react with the substrate 20 to create a monolayer. The third chambers 516 on either side of the unobstructed first chamber 512 prevent any second ALD precursor to escape from under the cover 560 and prematurely intermix with the first ALD precursor gas reacting with the substrate 20. Then, the rotating plate 511 is rotated to place one second chamber 514 beneath the substrate 20 to allow reaction of the second ALD precursor gas with the first ALD precursor gas and the substrate 20 to create a second monolayer.

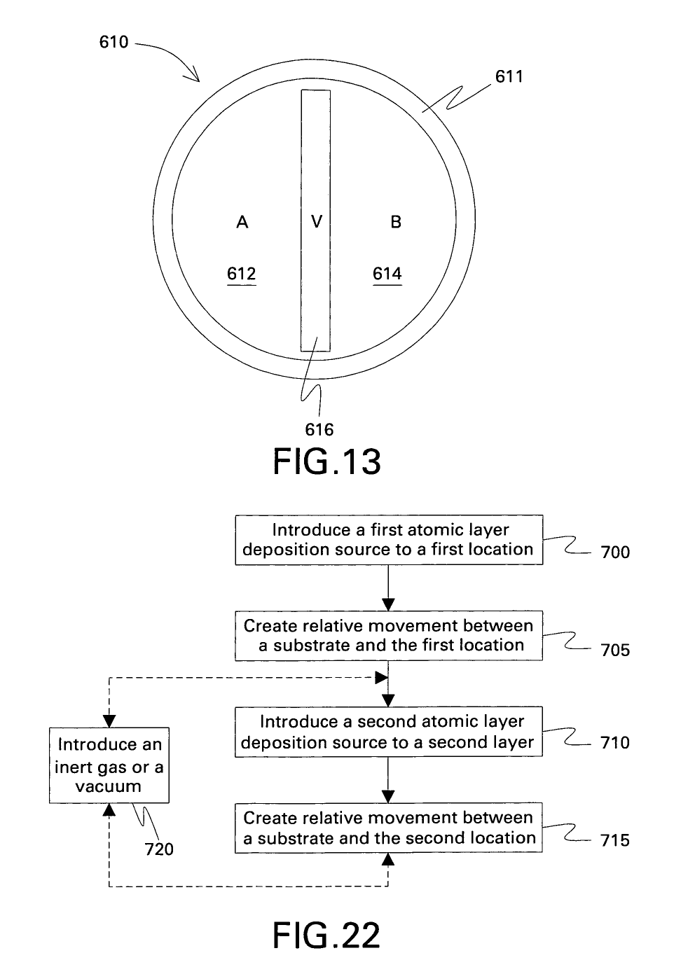

FIG. 13 illustrates a roll-to-roll device 610. Device 610 is a simplified version of device 510 in that it includes a single first ALD chamber 612 separated from a single second ALD chamber 614 by a vacuum chamber 616. A cover (not shown) can cover one of the ALD chambers while the uncovered ALD chamber dispenses the ALD precursor gas to the substrate (also not shown).

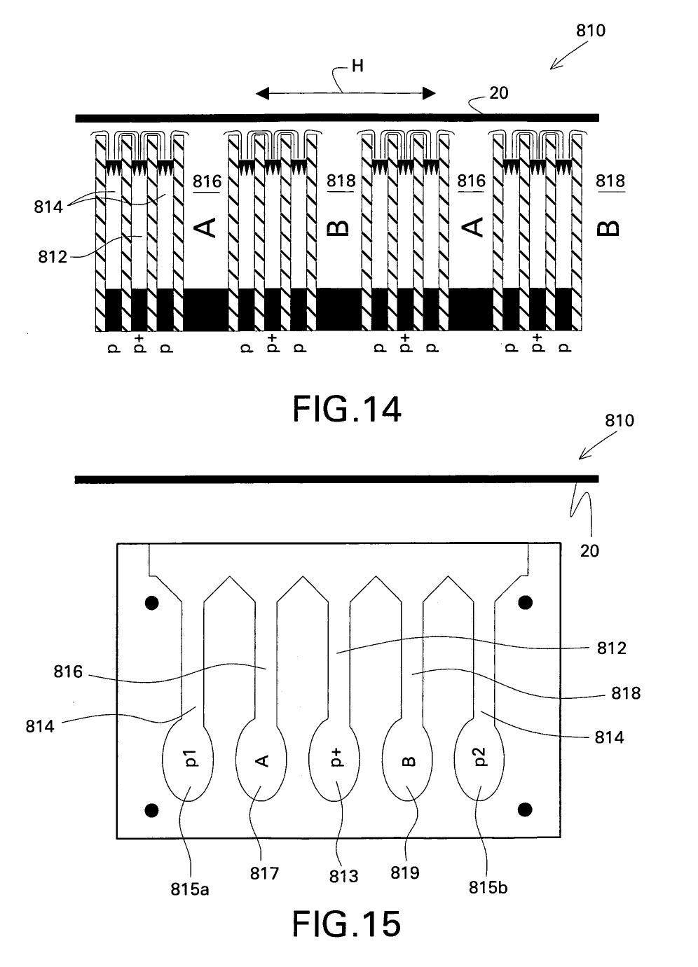

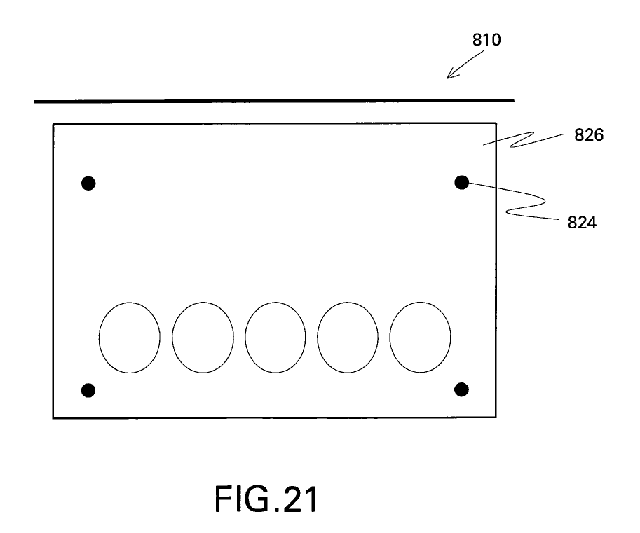

With reference now to FIGS. 14-21 will be described a roll-to-roll device 810. A baffle system is utilized to separate a first ALD precursor gas A from a second ALD precursor gas B. Specifically, an inlet 812, surrounded by outlets 814, is positioned between a first ALD chamber 816 (for precursor gas A) and a second ALD chamber 818 (for precursor gas B). The inlet 812 is at a slightly higher pressure than the outlets 814 or the chambers 816, 818. An inert or a carrier gas is input to the inlet 812. The slightly lower pressure of the outlets 814 allows the inert or carrier gas to output through the outlets 814. In addition, either of the precursor gases A, B may output through the outlets 814. Through this arrangement, the precursor gases A, B are kept separate from one another, and the precursor gas A can form a first monolayer on the substrate 20 moving in a direction H and the second precursor gas B can form a second monolayer on the first monolayer.

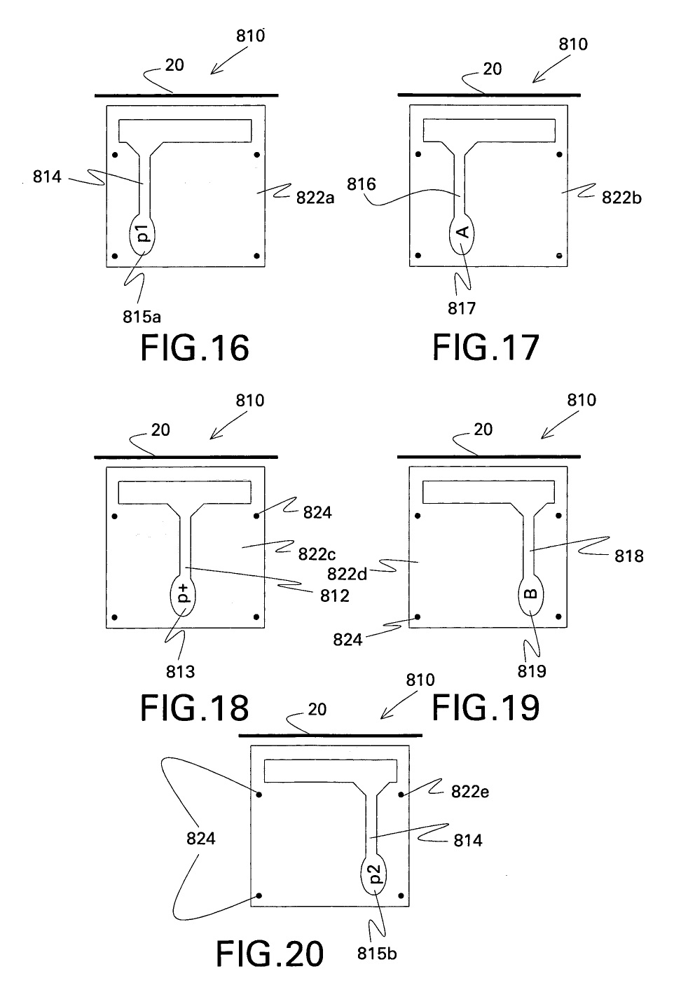

The baffle system of FIG. 14 requires five connections, namely a connection 817 for chamber 816, a connection 819 for chamber 818, a connection 813 for the inlet 812, and connections 815_{a,b} for the outlets 814 (FIG. 15). As shown in FIGS. 16-20 a separate spacer layer is provided with a connection and channel portion. In FIG. 16, a spacer 822ₐ is provided that includes the connection 815a and the outlet 814. In FIG. 17, a spacer 822_{b} is provided that includes the connection 817 and the chamber 816. In FIG. 18, a spacer 822_{c} is provided that includes the connection 813 and the inlet 812. In FIG. 19, a spacer 822_{d} is provided that includes the connection 819 and the chamber 818. And, in FIG. 20, a spacer 822ₑ is provided that includes the connection 815_{b} and the second outlet 814. Each of the spacers 822 may be aligned through alignment pins 824. Sheets 826 (FIG. 20) may be employed between the spacers 822 including orifices for the connections 815ₐ, 815_{b}, 813, 817, and 819. The sheets 826 are aligned with the spacers 822 through the alignment pins 824.

Next, with specific reference to FIG. 22, is described a method for performing a continuous roll-to-roll atomic layer deposition upon a substrate, such as substrate 20. At Step 700, a first atomic layer deposition source, such as an ALD precursor gas, is introduced to a first location. The first precursor gas creates a monolayer on the surface of the substrate 20 while the substrate 20 is at the first location. Next, at Step 705, relative movement is created between a substrate and the first location. Moving the substrate past the first location or moving the first location from the substrate may create the relative movement. Then, at Step 710, a second atomic layer deposition source is introduced to a second location. The second precursor gas creates a second monolayer on the substrate 20 while the substrate 20 is at the second location. An optional Step 720 may be insert between Steps 705 and 710, namely an inert or carrier gas or a vacuum may be introduced at the first location. The inert or carrier gas, or the vacuum, serves to carry out any remaining removable first precursor gas. After Step 710, relative movement is created between the substrate and the second location. Moving the substrate past the second location or moving the second location to the substrate may create the relative movement. Again, an optional Step 720 may be inserted after Step 715. It should be understood and appreciated that Steps 700 through 715 (an optionally 720) may be repeated as many times as necessary or desired.

It should be appreciated that certain mechanical and chemical properties are desirable for substrates to be used in electronic devices such as organic light-emitting devices (OLEDs), organic photovoltaic devices, thin-film transistors (TFTs) and TFT arrays using organic and solution-processible inorganic materials, and other more complicated circuits. Mechanical flexibility of the substrate is of importance for roll-to-roll processing, as described herein. Similar flexibility is also required for various end-use applications, such as, for example, “roll-up” displays. Chemical resistance is also important for substrate compatibility with the various solvents and chemicals in use in organic electronic device fabrication steps. Further discussion of important mechanical and chemical properties for suitable substrates is found in M. Yan, et al., “A Transparent, High Barrier, and High Heat Substrate for Organic Electronics,” IEEE, V. 93, N. 8, August 2005, p. 1468-1477, the entirety of which is incorporated herein by reference.

The devices and method described herein are advantageous in that they increase deposition rate by reducing the cycle time required for exposing a surface of an object, such as the substrate 20, to, in sequence, first and second precursor gases. The deposition rate is also increased through the use of a roll-to-roll ALD process.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. For example, while use of the plasma source 30, or other surface activation techniques, such as, for example, electron-beam, ultraviolet, ozone, corona, or AC or DC sputtering has been described with reference to the FIG. 1 embodiment, it should be understood that such techniques may be incorporated in any of the embodiments described. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed as new and desired to be protected by Letters Patent of the United States is:

1. A continuous roll-to-roll atomic layer deposition device:

2. The device of claim 1, comprising:
at least one first chamber adapted for receiving a first precursor gas;
at least one second chamber adapted for receiving a second precursor gas; and
at least one roller configured to allow a substrate to be transported through said first and second chambers;
wherein said first precursor gas forms a first monolayer on the substrate and said second precursor gas forms a second monolayer on the substrate.

3. The device of claim 2, comprising a third chamber adapted for receiving an inert gas, said third chamber being sequentially positioned between said first and second chambers.

4. The device of claim 2, further comprising a surface activation mechanism positioned in at least one of said first and second chambers, wherein said surface activation mechanism comprises at least one from the group consisting of plasma source, electron-beam, ultraviolet, ozone, corona, AC sputtering, and DC sputtering.

5. The device of claim 2, wherein said chambers comprise baffles to enable transport of said substrate between said chambers, said baffles being sized to inhibit deposition of said first precursor gas on said substrate in any chamber other than said first chamber and to inhibit deposition of said second precursor gas on said substrate in any chamber other than said second chamber.

6. The device of claim 2, wherein said first and second chambers are maintained at a first pressure and are separated from each other with an area at a second pressure higher than said first pressure.

7. The device of claim 1, comprising:
at least one first chamber adapted for receiving a first precursor gas;
at least one second chamber adapted for receiving a second precursor gas, each said at least one first chamber being separated from each said at least one second chamber by a wall having a baffle; and
a transportation device for transporting a substrate past said at least one first and second chambers to form an atomic layer deposition upon the substrate.

8. The device of claim 7, wherein said baffle comprises a ledge.

9. The device of claim 8, wherein said ledge comprises teeth.

10. The device of claim 7, comprising at least one third chamber, each said at least one third chamber being positioned between one each of said at least one first and second chambers.

11. The device of claim 1, comprising:
at least one first chamber adapted for receiving a first precursor gas;
at least one second chamber adapted for receiving a second precursor gas;
at least one third chamber adapted for receiving a carrier or inert gas, each said at least one third chamber separating one each of said at least one first and second chambers; and
a transportation device for transporting a substrate past said at least one first, second, and third chambers to form an atomic layer deposition upon the substrate.

12. The device of claim 1, comprising:
at least one first chamber adapted for receiving a first precursor gas;
at least one second chamber adapted for receiving a second precursor gas;
at least one vacuum chamber separating said at least one first and second chambers; and
a transportation device for transporting a substrate past said chambers to form an atomic layer deposition upon the substrate.

13. The device of claim 12, comprising at least one third chamber adapted for receiving a carrier or inert gas.

14. The device of claim 1, comprising:
a chamber adapted to enable the transportation of a substrate there through;
a set of first and second piping, said set comprising piping and valves to enable sequential and separate introduction of, respectively, a first precursor gas and a second precursor gas; and
a set of third piping for inhibiting premature intermixing of the first precursor gas with the second ALD precursor gas.

15. The device of claim 14, wherein said third piping comprises vacuum piping for sequential evacuation of said chamber between introduction of each of said first and second precursor gases.

16. The device of claim 14, wherein said third piping comprises carrier or inert gas piping for introduction of a carrier or inert gas between introduction of each of said first and second precursor gases.

17. The device of claim 1, comprising:
a rotatable disc including:
at least one first chamber adapted for receiving a first precursor gas;
at least one second chamber adapted for receiving a second precursor gas; and
at least one third chamber;
a cover partially obstructing said rotatable disc; and
a transportation mechanism for transporting a substrate past an unobstructed portion of said rotatable disc.

18. The device of claim 17, wherein each said third chamber is positioned between each said first and second chamber.

19. The device of claim 17, wherein said at least one third chamber is adapted for receiving a carrier or inert gas or for being induced to vacuum.

20. The device of claim 1 being configured to perform atomic layer deposition on a substrate formed of plastic film, plastic sheet, metal sheet, metal film, or glass sheet, or on optoelectronic devices that have been built on glass, metal or plastic substrates.

21. The device of claim 20, for forming organic light-emitting devices (OLEDs), flexible display coatings, RFIDs, MEMS, optical coatings, electronics on flexible substrates, thin films on flexible substrates, electrochromics, or photovoltaics.

22. A method for roll-to-roll atomic layer deposition of a coating on a substrate, comprising:
introducing a first gas source to a first location;
inducing relative motion between a substrate and the first location;
introducing a second gas source to a second location; and
inducing relative motion between the substrate and the second location;
wherein a first precursor gas from the first gas source forms a first monolayer on the substrate and a second precursor gas from the second gas source forms a second monolayer on the substrate.

23. The method of claim 22, wherein the first location comprises a first chamber adapted for receiving the first gas source.

24. The method of claim 22, wherein said inducing relative motion between a substrate and the first location comprises transporting the substrate past the first location.

25. The method of claim 24, wherein said transporting the substrate past the first location comprises placing the substrate upon a plurality of rollers providing sufficient force on the substrate as to move the substrate through the first location.

26. The method of claim 25, wherein said inducing relative motion between the substrate and the second location comprises transporting the substrate past the second location.

27. The method of claim 26, wherein said transporting the substrate past the second location comprises placing the substrate upon a plurality of rollers providing sufficient force on the substrate as to move the substrate through the second location.

28. The method of claim 27, wherein said transporting steps comprise winding the substrate through a plurality of rollers, a portion of which are positioned in the first location and another portion of which are positioned in the second location.

29. The method of claim 28, wherein the first and second locations are separated by a chamber adapted to receive an inert gas at a pressure higher than the pressure at the first and second locations.

30. The method of claim 28, wherein the introducing steps comprise introducing the first gas source to a plurality of first locations and introducing the second gas source to a plurality of second locations, wherein a portion of the plurality of rollers are positioned in one of the plurality of first locations and a portion of the plurality of rollers are positioned in one of the plurality of second locations.

31. The method of claim 22, further comprising introducing a surface activation technique at either the first location or the second location, wherein said surface activation technique comprises at least one from the group consisting of plasma source, electron-beam, ultraviolet, ozone, corona, AC sputtering, and DC sputtering.

32. The method of claim 22, wherein said inducing relative motion between a substrate and the first location comprises moving the first location adjacent the substrate.

33. The method of claim 32, wherein said moving the first location adjacent the substrate comprises rotating the first location to an unobstructed position adjacent the substrate.
